(19) United States
(12) Patent Application Publication
(10) Pub. No.: US 2012/0057313 A1
(43) Pub. Date: Mar. 8, 2012

(54) PACKAGE FOR SYSTEM LEVEL ELECTRONIC PRODUCTS

(75) Inventors: Artur DARBINYAN, Santa Clara, CA (US); Kurt E. SINCERBOX, San Jose, CA (US); David T. CHIN, Cupertino, CA (US)

(73) Assignee: NATIONAL SEMICONDUCTOR CORPORATION, Santa Clara, CA (US)

(21) Appl. No.: 12/876,002

(22) Filed: Sep. 3, 2010

(51) Int. Cl. H05K 5/00; B29C 39/10; H05K 7/00

(52) U.S. Cl. 361/752; 361/748; 264/257

(57) ABSTRACT

Methods and arrangements for packaging system level electronics are described. In one aspect, an external skin of the package is formed from isolation paper. In some embodiments, the isolation paper is formed into a box. A printed circuit board is placed within the isolation paper skin and is substantially completely surrounded by a potting material that substantially completely fills the skin. The potting material is cured to solidify the potting material within the isolation paper box and to adhere the potting material to the isolation paper such that the isolation paper forms a skin for a brick of potting material that encapsulates the printed circuit board. The isolation paper skin includes at least one opening that permits an interconnect to be exposed through the skin. With this arrangement, a packaged electronics device is provided and the isolation paper forms the exposed outer surface of the packaged electronics device. The described package is particularly well suited for use in packaging system level power electronics such as power supplies.

### BACKGROUND OF THE INVENTION

The present invention relates generally to the packaging of system level electronic products. The invention is particularly well suited for use in packaging power electronics products.

System level power electronic products (such as power supplies) generally include a number of electrical components mounted on a printed circuit board. The printed circuit board is typically housed in an enclosure such as a plastic or metal casing. Often a potting compound or a conformal coating is applied to the printed circuit board and the components mounted thereon to electrically isolate the various electronic components from the casing, each other and/or external exposure. When metal casings are used, isolation paper is often used to help further electrically isolate the metal casing from the electrical components mounted on the printed circuit board.

Although existing system level power products packaging arrangements work well, there are continuing efforts to provide more cost effective, reliable methods and arrangements for packaging power supplies and other system level power electronics.

### SUMMARY OF THE INVENTION

Improved methods and arrangements for packaging system level electronics are described. In one aspect, an external skin of the package is formed from isolation paper. A printed circuit board is placed within the isolation paper skin and is substantially completely surrounded by a potting material that substantially completely fills the skin. The printed circuit board supports and carries a plurality of electronic components. At least one electrical interconnect is provided to electrically couple the printed circuit board and/or selected electrical components carried by the printed circuit board to external devices. The isolation paper skin substantially completely surrounds the printed circuit board and includes at least one opening that permits the interconnect to be exposed outside of the skin. The described package is particularly well suited for use in packaging system level power electronics such as power supplies.

In some method aspects of the invention the isolation paper is formed into a box. A populated printed circuit board is placed into the isolation paper box and potting material is dispensed into the box. The potting material is arranged to substantially completely surround the printed circuit board and substantially fills the isolation paper box. The potting material is then cured to solidify the potting material within the isolation paper box and to adhere the potting material to the isolation paper such that the isolation paper forms a skin for a brick of potting material that encapsulates the printed circuit board. With this arrangement, a packaged electronics device is provided and the isolation paper forms the exposed outer surface of the packaged electronics device.

In some embodiments the potting material is dispensed in multiple steps. In one preferred approach, a first volume of potting material is dispensed into the isolation paper box before placing the printed circuit board into the box. The printed circuit board is then placed on the viscous potting material and thereafter additional potting material is dispensed over the printed circuit board to top off the box before curing.

### BRIEF DESCRIPTION OF THE DRAWINGS

The invention and the advantages thereof, may best be understood by reference to the following description taken in conjunction with the accompanying drawings in which:

FIG. 1 is a perspective view of a packaged electronic device is accordance with one embodiment of the present invention.

FIG. 2 is a flow chart illustrating a method of packaging a system level electronics device in accordance with one embodiment of the present invention.

FIG. 3 is a top view of a cut sheet of isolation paper suitable for forming the external skin of a packaged electronics device in accordance with one embodiment of the present invention.

FIG. 4 is a perspective view of the sheet of isolation paper illustrated in FIG. 3 folded to form a packaging container skin for an electronics device that includes a printed circuit board.

FIGS. 5(a)-5(d) illustrate various steps in packaging of an electronic device in accordance with the method of FIG. 2.

FIG. 6 illustrates a prior art power supply package that includes a metal casing.

FIG. 7 illustrates a prior art power supply package that includes a plastic casing.

FIG. 8 is a diagrammatic illustration showing the packaged electronic device of FIG. 1 mounted using a bracket.

FIG. 9 is a diagrammatic illustration showing the packaged electronic device of FIG. 1 mounted using a heat sink bracket.

In the drawings, like reference numerals are sometimes used to designate like structural elements. It should also be appreciated that the depictions in the figures are diagrammatic and not to scale.

### DETAILED DESCRIPTION OF THE PREFERRED EMBODIMENTS

The present invention relates generally to the packaging of system level products such as power supplies. In general, a printed circuit board having a plurality of electrical components is placed in a box formed from isolation paper. The box is filled with a potting compound such that the electrical components are encased within a brick of potting compound within the isolation paper, with the isolation paper effectively serving as a skin for the packaged brick.

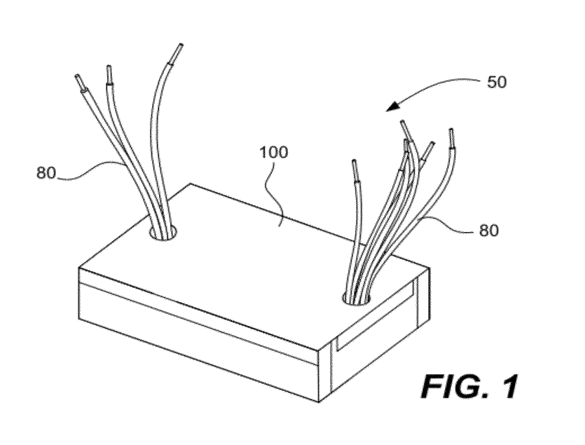

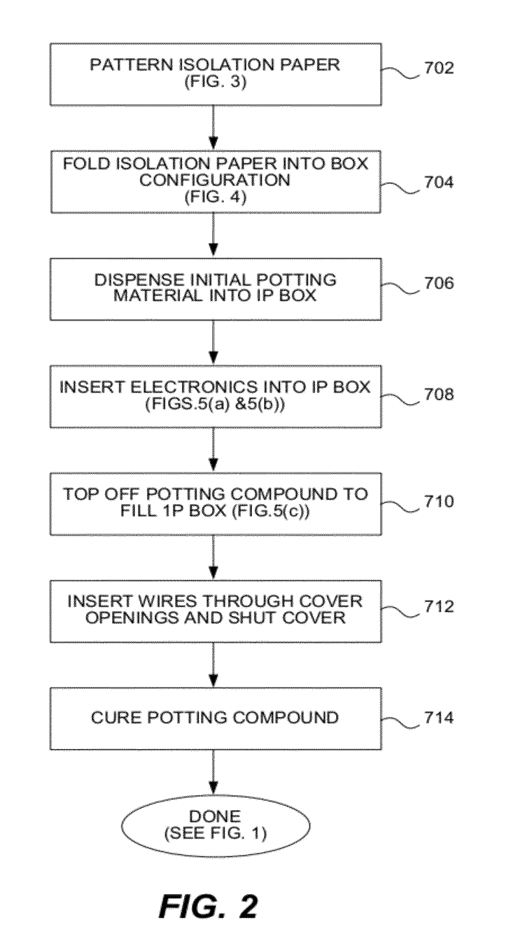

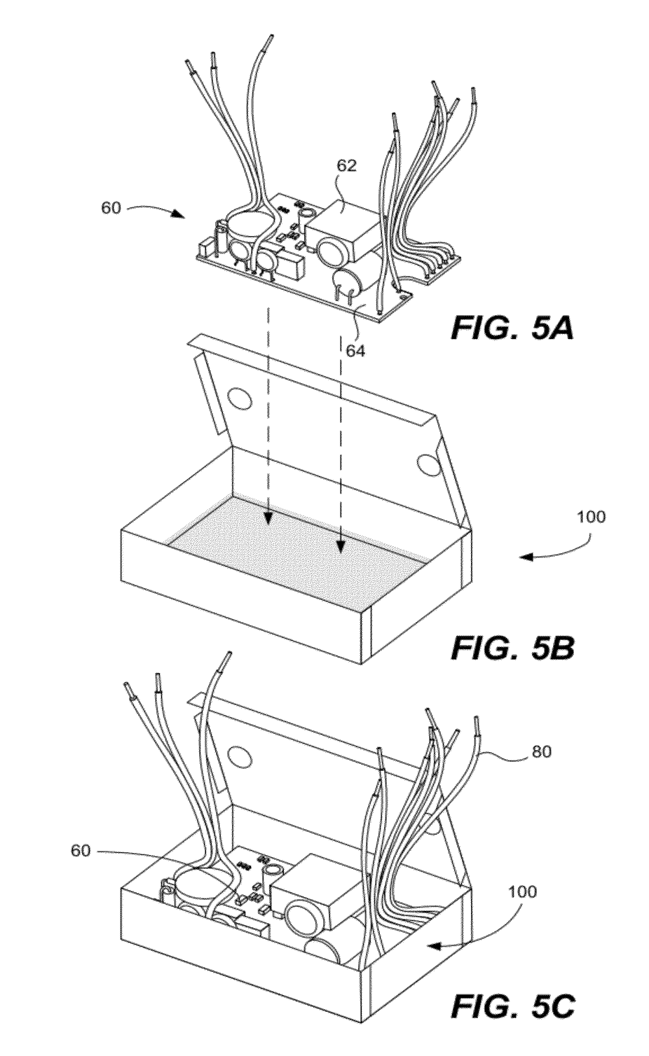

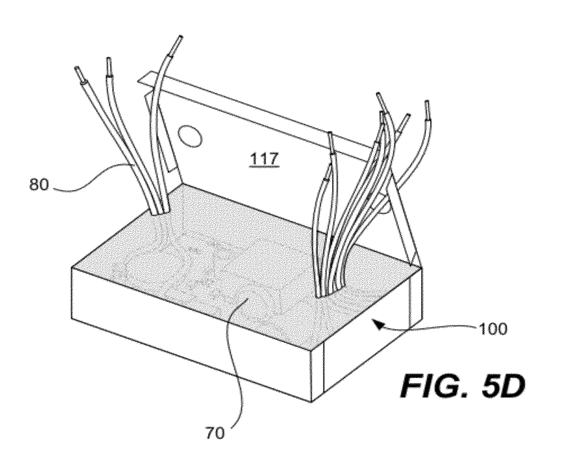

A packaged electronic device 50 in accordance with one embodiment of the present invention is illustrated in FIG. 1. As best understood with reference to FIGS. 5(a)-5(d), in the illustrated embodiment, electronics 60 are fully immersed in a brick of potting material 70 with an exposed electrical interconnect. In the illustrated embodiment, the electrical interconnect takes the form of a plurality of wires 80 that extend from the brick, although in other embodiments the interconnect may take the form of a connector, terminals, headers and/or other suitable structure. The specific electronics will vary significantly based on the nature of the packaged product but generally will include a number of electrical components 62 mounted on a printed circuit board 64. The electrical interconnect is typically electrically coupled to associated components 62 or the printed circuit board 64. The interconnect (e.g. wires 80) is intended to facilitate electrical connection of the electronics 60 to external devices.

The potting material 70 is encased by a box 100 formed of isolation paper. The potting material 70 substantially completely fills the isolation paper box 100 and preferably surrounds the electronics 60 on all sides such that none of the components of electronics 60 physically touch the isolation paper. With this arrangement, the electrical components are electrically isolated from external devices by both the isolation paper 100 and the potting material 70. The wires 80 pass through openings in the isolation paper box 100 to facilitate electrical connection the electronics 60 to external devices. The isolation paper 100 acts as an external skin for the packaged device which is housed in a solid brick of potting material. This provides a very robust, low cost and reliable package with good heat dissipation characteristics and very good electrical isolation characteristics.

As will be appreciated by those familiar with the art, isolation paper is generally a flame retardant material having good electrical isolation properties (e.g., high electrical resistance and high dielectric constant) and is available from a number of suppliers. The thickness and electrical properties of the isolation paper may be selected to meet the needs of any particular application, although it is typically not necessary for the isolation paper to be particularly thick when the electronics are fully potted as will be described in more detail below.

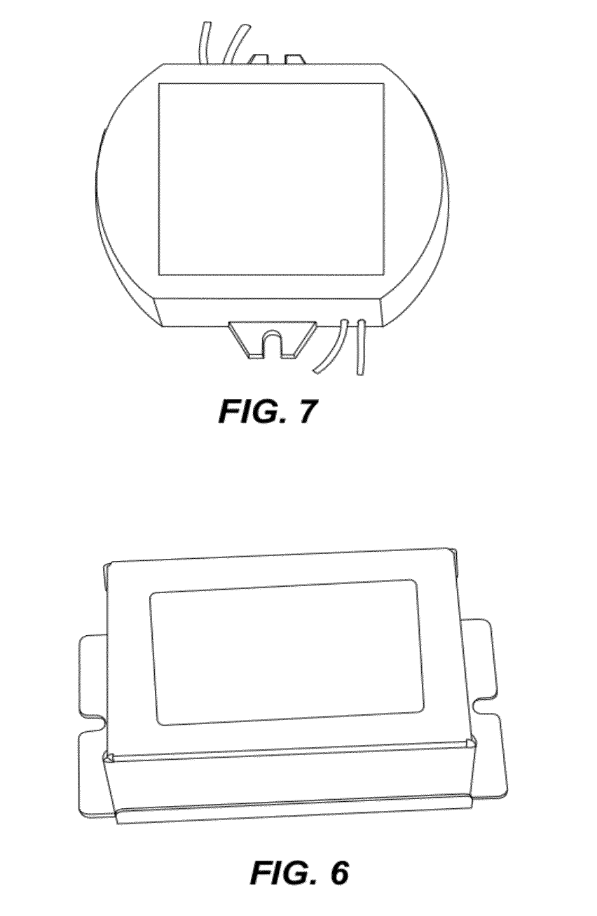

It is particularly notable that the isolation paper 100 forms the external skin for the package. This is quite different than the packaging of conventional system level power electronics which are typically housed within a metal or plastic enclosure as illustrated in FIGS. 6 and 7. As will be appreciated by those familiar with the packaging of system level power electronics, when metal enclosures are used, isolation paper is sometimes used to help electrically isolate electronic components from the metal casing. In such arrangements, the electronics are typically placed within a “box” formed from isolation paper. Sometimes a potting material is also dispensed within the isolation paper to help further electrically isolate the electrical components from the metal casing and to help hold the electronics in place. The potting material also provides environmental protection and helps with thermal dissipation. To the knowledge of the inventor, such potting material does not traditionally fill the isolation paper box because the metal casing is intended to provide the required structural support. In contrast, in the present invention, isolation paper is used as the exterior skin for the packaged product. That is, the packaged product is not placed within a metal (or other) enclosure. This is a very different configuration than the prior art and has a number of significant advantages.

Initially, the isolation paper/potting compound brick packaging approach is believed to be significantly cheaper than conventional metal or plastic casing packages. For example, one cost analysis estimated that the isolation paper/potting compound brick package would provide a savings of over 30% on the materials used to package power electronics devices relative to packaging that utilizes metal or plastic enclosures. However the cost of materials saving is just one of the advantages of using the described package. The tooling costs savings and the improved lead time to get a finished product produced are even more pronounced. For example, when a metal enclosure is used, it may take on the order of 4 weeks and cost on the order of $20 k to produce the necessary tools to form the metal enclosure. When a plastic enclosure is used, it may take on the order of 8-10 weeks and cost on the order of $25 k to produce the necessary molds for the plastic enclosure. In contrast, when the described isolation paper/potting compound brick packaging approach is used, the appropriate isolation paper can likely be designed and delivered within a week or less at a fraction of the tooling costs. This permits very rapid product development cycles and allows product packaging changes to be implemented almost immediately for a fraction of the costs that are associated with developing and/or altering conventional plastic or metal casings. In some situation, the short lead times associated with the isolation paper/potting compound brick approach are even more important than the cost of materials savings.

The described packaging arrangement may be used to package virtually any type of electronics. However, it is particularly well suited for the packaging of system level power electronics. By way of example, the described process is well suited for use in the packaging of power supplies. The described packages are very robust. This is in part because isolation paper itself is quite strong and in part because the potting material brick provides a very strong foundation for the isolation paper. Therefore, the described packages are suitable for use in a wide variety of applications.

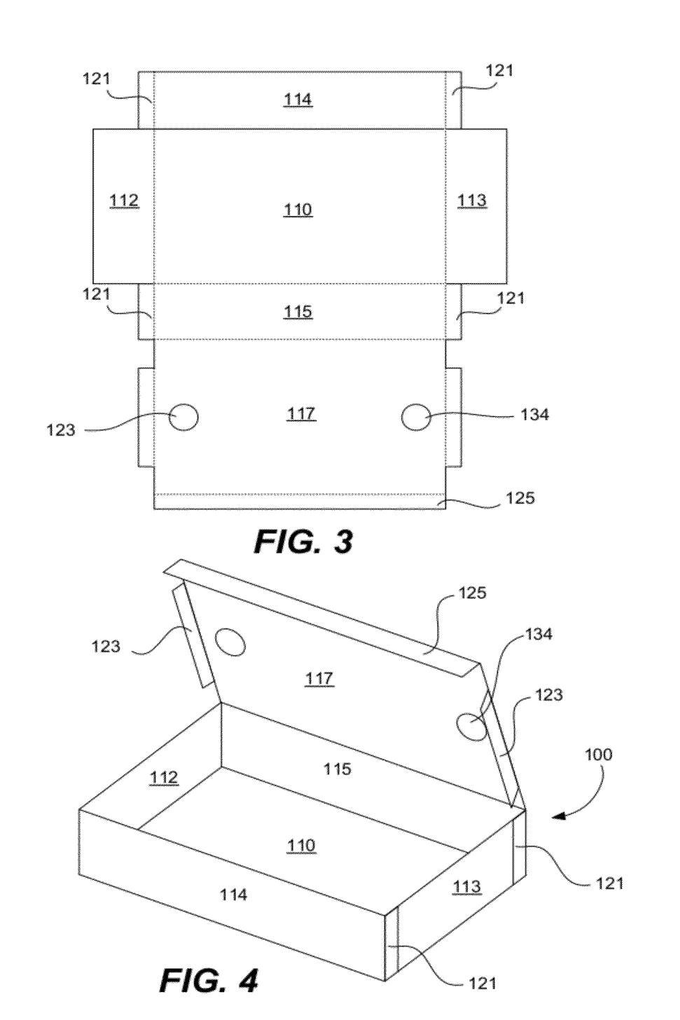

Referring next to FIG. 2 in conjunction with FIGS. 3-5, a method of packaging a system level electronics product that uses the isolation paper box as the exterior skin for the package will be described. Initially in step 702, a sheet of isolation paper 101 is patterned in a manner suitable for forming an origami box 100. The actual geometry of the sheet 101 and the resulting box 100 may vary widely to meet the needs of any particular package. By way of example, in the embodiment illustrated in FIG. 3, the sheet 101 is divided into a number of sections by slits 104 and fold lines 106 (indicated as dashed lines in FIG. 3). The illustrated sections include a bottom wall 110, opposing end walls 112 and 113, front wall 114, back wall 115 and lid 117. The front and back walls 114 and 115 each include a pair of flaps 121 that are each arranged to fold over an associated end wall 112, 113. The lid section 117 also includes a plurality of flaps 123 that are each arranged to fold over an associated end wall and a flap 125 that is arranged to fold over the front wall 114. In the illustrated embodiment, the lid section 117 also has a couple of holes 134 that are arranged to allow wiring to exit the box 100. Although two holes 134 are shown, it should be appreciated that the number of holes and their respective geometries may be widely varied to meet the needs of any particular package.

There are a number of vendors that sell isolation paper and typically the patterning of the isolation paper would be done by the vendor (although that is not a requirement). The isolation paper sheet 101 may be folded to form a box 100 as illustrated in FIG. 4. (Step 704). If desired, adhesive may be applied to the flaps (or on the surfaces that the flaps contact) to help hold the box together in a self supporting manner, although that is not necessary as will be described in more detail below. If adhesive is used, the adhesive may be provided by the isolation paper vendor or it may be applied when the box is folded. Although one particular box structure has been illustrated, it should be appreciated that the actual geometry of both the isolation paper sheet 101 and the box 100 may be varied widely to meet the needs of any particular package.

After the isolation paper box 100 has been formed, the isolation paper box 100 may optionally be placed in a support cavity (not shown). When used, the support cavity preferably tightly holds the isolation paper so that it holds its box form during the subsequent potting operations. This is particularly helpful when the box is not adhered together. In other embodiments (and particularly in embodiments where the isolation paper box is self-supporting), there may be no need to place the box in a support cavity.

Once the box is properly placed, some potting material 71 is dispensed into the isolation paper box 100. Step 706. The initial dispensing of potting material partially fills the box. After the initial potting material 71 is dispensed, the electronics 60 are placed into the box 100 over the initial potting material. Step 708, FIG. 5(a-b). The electronics are set such that the printed circuit board effectively rests on top of the initial potting material 71. Thus, the potting material can be used to define the set-off distance between the isolation paper and the bottom surface of the printed circuit board 64. If any electrical components extend from the bottom surface of the printed circuit board, the printed circuit board is pressed into place so that any components on the lower surface of the printed circuit board 64 press into the potting material while the printed circuit board itself still floats on the initial potting material as best seen in FIG. 5(c).

After the electronics have been placed in the box 100, additional potting material is dispensed into the box to substantially fill the box. Step 710, FIG. 5(d). In the described embodiment, the dispensing of the potting material is done in two stages. One advantage of the two stage dispensing approach is that it gives good control over the standoff distance between the isolation paper box 100 and printed circuit board 64 (and thus the components carried on the printed circuit board). Another advantage of the two stage potting process is that it inherently helps reduce the probability of air gaps forming within the potting material below the printed circuit board. Although a two stage dispensing process is generally preferred, it is not necessary and it is possible to dispense the potting material in a single stage. In still other embodiments, it may be desirable to dispense the potting material in more than two stages. By way of example, additional dispensing stages may be desirable in certain circumstances where multiple components are placed into the box separately and there is a desire to vertically separate the components within the potting compound.

After the potting compound has been topped off, the wires 80 are inserted through the lid openings 134 and the lid section 117 is lowered into place to effectively close the box 100. Step 712. With this arrangement, the wires 80 extend out from the top of the closed isolation paper box 100 as seen in FIG. 1. The lid section is preferably brought into contact with the potting material so that the lid affirmatively adheres to the potting material.

After the lid has been closed, the potting material is cured to form a solid brick that encases the electronics 60. Step 714. The nature of the cure will depend largely on the type of potting material used in any particular application. A wide variety of conventional electronics potting materials may be used as the potting material 70. By way of example, traditional epoxy, urethane, silicon and acrylic based potting compounds can all work well. The potting material preferably has an adhesive quality so that when it cures it affirmatively bonds to the isolation paper 100. This securely holds the isolation paper in place when the packaging is completed. A side benefit of the described approach is that any flaps (e.g. flaps 121, 123, 125) that are not already adhesively bonded to their associated walls will be adhered by the potting material itself.

As mentioned above, when a support cavity is used to hold the isolation paper box during the potting operations, it is not necessary to adhere the flaps to their associated walls before the potting operation begins. This can simplify the isolation box assembly, but has the potential drawback of requiring the creation of suitable support structures. In practice, the support structures would often be relatively large matrixes of support cavities that permit the simultaneous potting of many devices. Alternatively, when the box is assembled in a self-supporting manner prior to the potting operation, the need for a support cavity can be eliminated—that is, the potting can be done without the need for a support cavity which eliminates the potential need to locate or fabricate a suitable support structure before production begins.

The described package is very strong and durable, has good thermal dissipation and flame resistance characteristics, has a good ingress protection (IP) rating and is suitable for use in a variety of applications. The described isolation paper/potting compound brick packaging structure can be used in a wide variety of electronic packaging applications. It is believed that that the described package is particularly well suited for use in the packaging of system level power electronics products such as power supplies. However, it should be appreciated that the described approach is not limited to power electronics products. One particular application of interest is for the power supplies used in LED downlighting.

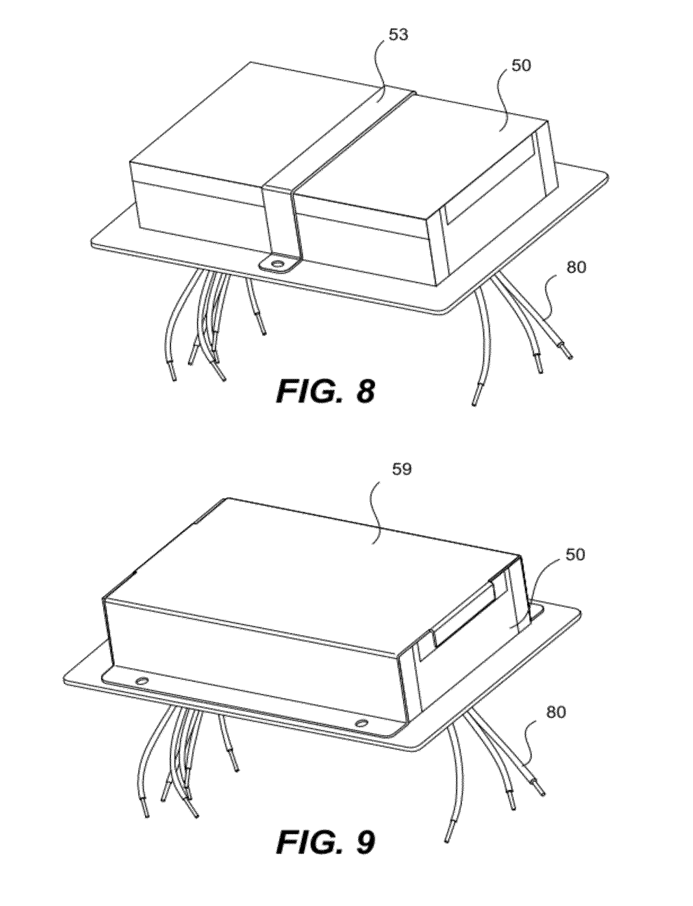

Since the described package 50 is quite strong, it may be mounted directly to any suitable support structure during use. By way of example, in the embodiment of FIG. 8, a small bracket 53 may be used to secure the package 50 to a support structure 59 such as a base plate, a frame or any other suitable structure. By way of example, in an LED downlighting application, the support structure 59 may be the light can frame that holds the LED. Of course, the described package 50 may be used with a wide variety of other support structures as well.

In some applications, a power electronics device packaged in accordance with the present invention may generate a significant amount of heat, and therefore it may be desirable to provide a heat sink that helps cool the device. Heat sinks can be applied to the packaged electronics device 50 in a variety of manners. One simple approach is illustrated in FIG. 9. In the illustrated embodiment, a relatively wide, generally U-shaped bracket 55 is used to secure the packaged electronics device to a support 59 (which again, may be a base, a frame or any other suitable structure). The U-shaped bracket contacts several sides of the packaged electronics device 50, which helps disapate heat and thereby serving as an effective heat sink.

Although only a few embodiments of the invention have been described in detail, it should be appreciated that the invention may be implemented in many other forms without departing from the spirit or scope of the invention. The specifications of the isolation paper have not been discussed in detail herein because they are believed to be well understood by those familiar with the art. Isolation paper is typically provided in sheet form and is available from a number of sources and may have a variety of constituents. For example, some types of isolation paper take the form of a polypropylene sheet. As will be appreciated by those familiar with the art, there are a number of suppliers of isolation paper. Those suppliers include Formex, 3M, Sumitomo and DuPont. The specific characteristics of the isolation paper may be widely varied to meet the specifications or requirements of any particular application. However, by way of background, it is pointed out that isolation papers generally have appropriate flame retardant characteristics, high electrical resistance, high dielectric strength, a relatively high thermal index and an appropriate heat deflection temperature. Different vendors refer to their products as insulating paper, flame retardant sheets, etc. By way of example, suitable isolation papers include Formex GK flame retardant polypropylene sheets available from Formex of Addison Ill. The appropriate specifications for the isolation paper will vary based on the nature of the application. By way or example, for many applications isolations papers having the following characteristics work well: 1) a V-0 flame rating; 2) a dielectric strength of 2000 volts/mil or greater; 3) a relative heat deflection temperature of at least 120 degrees Centigrade; and 4) a relative thermal index of over 110 degrees C.

In the illustrated embodiment, wires 80 extend from the potting compound brick to facilitate electrical connection to external devices. However, it should be appreciated that a wide variety of alternative electrical connectors, terminals, headers, etc. may be used as the electrical interconnect in place of or in addition to the wires. In some implementations, the interconnect(s) may have structures (e.g. wires, connectors, etc.) that extend through and outside of the isolation paper. In other applications, the interconnect(s) (e.g., terminals, connectors, etc.) may merely be exposed through the openings. In various embodiments, the multiple different types of interconnects may be used.

In the illustrated embodiment, the isolation paper used to form the package skin takes the form of a single sheet. Although this arrangement is particularly convenient from a process standpoint, it is not required. Therefore, the present embodiments should be considered illustrative and not restrictive and the invention is not to be limited to the details given herein, but may be modified within the scope and equivalents of the appended claims.

What is claimed is:

1. A packaged electronics device consisting essentially of:
a populated printed circuit board that supports and carries a plurality of electronic components;
an external interconnect electrically coupled to at least one of the printed circuit board or a selected one of the electrical components carried by the printed circuit board;
a skin formed from isolation paper that substantially completely surrounds the printed circuit board, wherein the skin includes at least one opening that permits at least a portion of the interconnect to be exposed through the skin; and
a potting material that substantially completely surrounds the printed circuit board and the electrical components carried thereon, wherein the potting material substantially completely fills the skin.

2. A packaged electronics device as recited in claim 1 wherein the packaged electronics device is a power electronic device and the electronic components carried on the printed circuit board include at least one power semiconductor device.

3. A packaged electronics device as recited in claim 1 wherein the packaged electronics device is a power supply.

4. A packaged electronics device as recited in claim 1 wherein the isolation paper skin forms the outermost enclosure for the packaged electronics device.

5. A packaged electronics device as recited in claim 1 wherein the external interconnect includes a plurality of wires, each wire being electrically coupled to at least one of the printed circuit board or a selected one of the electrical components carried by the printed circuit board, and wherein free ends of the wires extend outside of the skin and pass through an associated one of the openings.

6. A packaged electronics device as recited in claim 1 wherein the external interconnect includes a connector that is exposed through an associated one of the openings.

7. A packaged electronics device comprising:
a populated printed circuit board that supports and carries a plurality of electronic components;
an external interconnect electrically coupled to at least one of the printed circuit board or a selected one of the electrical components carried by the printed circuit board;
a skin formed from isolation paper that substantially completely surrounds the printed circuit board, wherein the skin includes at least one opening that permits at least a portion of the interconnect to be exposed through the skin; and
a potting material that substantially completely surrounds the printed circuit board and the electrical components carried thereon, wherein the potting material forms a brick that adheres to and substantially completely fills the skin; and
wherein the isolation paper skin forms the outermost enclosure for the packaged electronics device.

8. A method of packaging electronics comprising:
placing a populated printed circuit board into a skin formed from isolation paper;
dispensing a potting material into a skin formed of an isolation paper, wherein the potting material substantially fills the skin; and
curing the potting material to solidify the potting material within the isolation paper skin, whereby a packaged electronics device is provided and the isolation paper forms the exposed outer surface of the packaged electronics device.

9. A method of packaging electronics as recited in claim 8 wherein the dispensing is performed in a plurality of steps including:
dispensing a first volume of potting material into the skin before placing the printed circuit board into the skin; and
dispensing a second volume of potting material into the skin after placing the printed circuit board into the skin.

10. A method of packaging electronics as recited in claim 8 wherein the skin includes an integral lid that includes at least one opening and the populated printed circuit board includes an external interconnect that is exposed through the at least one opening, and wherein the method further includes:
passing exposed portions of each external connection wires through an associated opening in the lid; and
folding the lid over an exposed open portion of the potting material to enclose the potting material.
